(19) United States
(12) Patent Application Publication
(10) Pub. No.: US 2009/0012651 A1
(43) Pub. Date: Jan. 8, 2009

(54) Including Energy Price in Optimizing Refrigerant System Operation

(76) Inventors: Alexander Lifson, Manlius, NY (US); Michael F. Taras, Fayetteville, NY (US)

Correspondence Address: CARLSON, GASKEY & OLDS, P.C., 400 WEST MAPLE ROAD, SUITE 350, BIRMINGHAM, MI, 48009, US

(21) Appl. No.: 12/160,356

(22) PCT Filed: Apr. 12, 2006
(86) PCT No.: PCT/US06/13726

§ 371 Date: Jul. 9, 2008

(51) Int. Cl. G05B 15/00; G01R 21/133

(52) U.S. Cl. 700/276; 705/412

(57) ABSTRACT

An HVAC & R system controller is provided with time pricing information for electricity and/or natural gas. This pricing information is utilized to determine the most efficient system configuration and operation schedule to achieve desired conditions in an indoor environment. As an example, if electricity prices are high, then the controller might rely on a natural gas powered furnace, rather than on the higher-electricity consuming heat pump. In another example, thermal storage media can be charged during off-peak hours when cost of electricity is low and release its thermal potential during high demand periods.

### BACKGROUND OF THE INVENTION

This application relates to a heating, ventilation, air conditioning and refrigeration (HVAC&R) system control which receives information such as pricing information for electricity and/or fuel (natural gas, heating oil, etc.) and utilizes this information to select a most efficient and economical method for operating the HVAC&R system.

HVAC&R systems are utilized to provide temperature and humidity controls for an environment to be conditioned such as a home, supermarket, office space, computer room or other building, as well as mobile units including (but not limited to) container refrigeration units and truck-trailer units. Typically, a control takes the information with regard to desired conditions, and determines the most efficient and reliable control strategy for operation of the HVAC&R system components and subsystems to achieve those desired conditions. Thus, as an example, a user or resident of the building may choose a desired temperature or humidity levels. The HVAC&R system control then controls components such as a heat pump, air conditioner, furnace, humidifier, chiller, cooling tower, etc., to achieve that desired temperature and humidity.

Certain HVAC&R system components consume significant amount of electrical power during operation. Others require less electricity, but may require some other resources such as natural gas. As an example, an air conditioning system or a heat pump require significant amount of electrical power, while a furnace requires less electricity.

It is well known that the pricing and availability of resources such as electricity or natural gas vary throughout the day and over the course of a year. It is especially true of the price of electricity, which is demand dependant, and can significantly vary over time, such as between morning and evening hours.

These variations have never been taken into account in optimally controlling an HVAC&R system.

### SUMMARY OF THE INVENTION

In a disclosed embodiment of this invention, pricing information for at least electricity is provided to a controller of an HVAC&R system. The information may be provided over the Internet or other information carrying media. This information can be provided via wired or wireless network. Alternatively, the pricing information may be learned or otherwise stored at the HVAC&R system database. Typically, the cost of electricity increases during the day, and decreases in the evening and nighttime hours. Thus, it would be preferable to rely less on electricity-intensive system components, such as a heat pump during the high priced day hours, and rely on those components more during the lower priced evening hours. Further, and even within the same time period, the pricing of electricity can vary due to various changes and can be included in the equipment control strategy.

The present invention communicates this pricing information to the controller. The controller than utilizes the pricing information to weigh the use of a component or subsystem, such as a heat pump or an alternative component such as a furnace with the cost of electricity. Should electricity be at a relatively high point in the day hours and additional heating is required for the environment to be conditioned, a controller might rely more on the furnace than the heat pump. Alternatively, later in the day, when electricity prices are lower, the controller may rely more on the heat pump.

Further, since every building structure has a thermal mass, it takes time and additional power consumption to bring it to desired conditions. For instance, it may be more efficient to cool the building structure during off-peak hours and maintain it at those conditions rather than use high-cost electricity during the day. Additionally, thermal storage media can be utilized, for instance, to be cooled at off-peak hours and release its cooling potential when electricity is at high demand and high cost. In other words, the optimal HVAC&R system control strategy is devised to superimpose sensible and latent capacity demands on the most cost-effective equipment operational configuration and time schedule.

Although these specific examples are disclosed, a worker of ordinary skill in the art would recognize that this is a powerful invention and can be utilized to achieve a number of other control features.

### BRIEF DESCRIPTION OF THE DRAWINGS

FIG. 1 is a schematic view of this invention.

FIG. 2 is a flow chart.

### DETAILED DESCRIPTION OF THE PREFERRED EMBODIMENTS

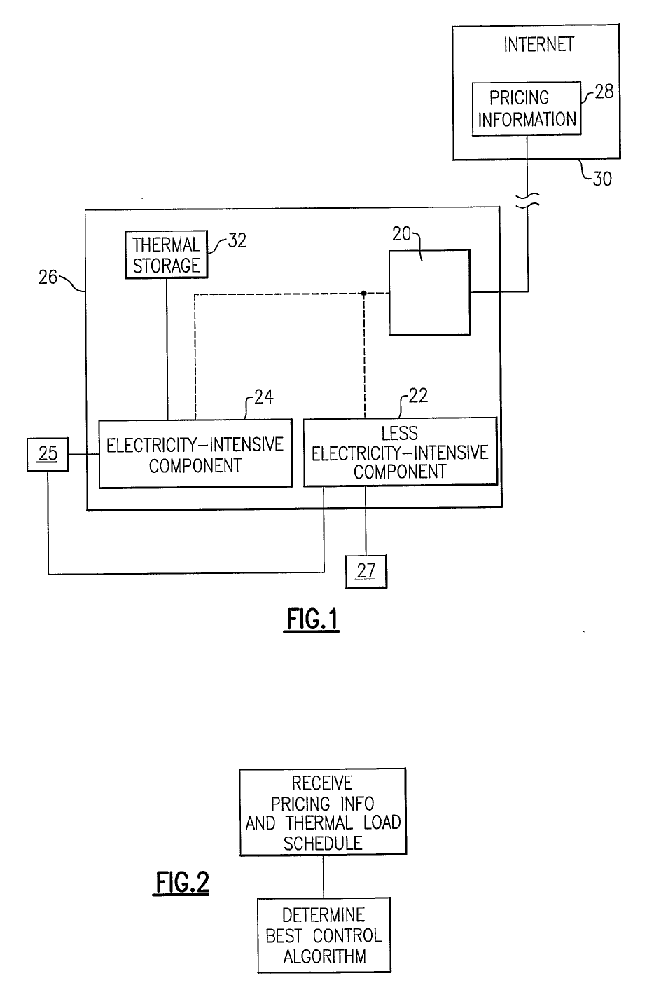

FIG. 1 shows a building 26 incorporating an HVAC&R system and a controller 20. As shown, the controller 20 may control the less electricity-intensive component 22, such as a furnace, and an electricity-intensive component 24, such as a heat pump. Heat pump 24 is provided with electricity from a source 25. Furnace 22 may typically be powered by natural gas, such as available from a source 27 and also consumes electricity from the source 25 but in a significantly lower amount than the heat pump 24. In the past, a controller 20 having the option of heating the building 26 with either the heat pump 24 or furnace 22 has not included any changes in the current pricing of electricity or natural gas in the decision-making process to devise the optimal cost-effective strategy of the HVAC&R system operational configuration and time schedule.

The present invention now provides a connection to a source of pricing information 28 such as over the Internet 30. The control is now provided with instantaneous pricing for the electricity from the source 25, and/or for natural gas (or the like heating media) from the source 27. The controller 20 can then select which of the two components 22 and 24 to rely upon at any particular point in time. This is shown in FIG. 2. As an example, in the daylight or working hours (peak hours), electricity is more expensive than it is in the evenings or nighttime hours (off-peak hours). At that point in time, should a need for additional heating of the building 26 occur, the controller might weigh the use of the furnace 22 (that uses natural gas) over the use of the heat pump 24 (that uses electricity) to reduce electricity consumption. Conversely, in the evenings, it may well be that the controller would weigh the use of the heat pump 24 over the use of the furnace 22 to reduce natural gas consumption.

By providing this pricing information over the Internet 30 to the controller 20, the present invention is thus able to more efficiently control the HVAC system, and provide the desired conditioning at less expense.

Further, the system controller 20 can “learn” to anticipate the pricing information. As an example, the controller 20 might simply learn or be previously programmed (such data is typically stored in the database) to assume that the pricing of electricity will decrease in the evening hours by a certain predicted amount, and can then utilize this information to achieve the adequate control.

Additionally, since every building structure has a thermal mass, it takes time and additional power consumption to bring it to desired conditions. For instance, it may be more efficient to cool the building structure during off-peak hours and maintain it at those conditions rather than use high-cost electricity during the day. Also, thermal storage media 32 can be utilized, for instance, to be cooled at off-peak hours and release its cooling potential when electricity is at high demand and cost, in order to supplement conventional cooling or replace it for a period of time. In other words, the optimal HVAC&R system control strategy is devised to superimpose sensible and latent capacity demands on the most cost-effective equipment operational configuration and time schedule. Analogously, the thermal storage can be employed for the heating purposes.

It has to be noted that if a thermal storage is utilized as an additional component to control the cooling or heating of the building structure, the furnace 22 may be an optional component (and therefore would not be needed and would not be a part of the schematic) as the presence of the heat pump component 24 may be sufficient enough to cool or heat the building. Further, the heat pump component 24 can be additionally simplified to function as just an air-conditioning unit, without any provisions for heating. In a similar fashion, by relying on the thermal storage control while using the furnace 22, the heat pump can be eliminated from the system schematic. An example of structures, applications, and conditioned environments that can be utilized as a part of this invention include home, supermarket, office space, computer room or other buildings, as well as mobile units such as container refrigeration units and truck-trailer units. Examples of the controlled components of the HVAC&R systems would include a heat pump, air conditioner, furnace, humidifier, chiller, cooling tower, and similar components, as known in the industry.

Although a preferred embodiment of this invention has been disclosed, a worker of ordinary skill in this art would recognize that certain modifications would come within the scope of this invention. For that reason, the following claims should be studied to determine the true scope and content of this invention.

1-28. (canceled)

29. An HVAC&R system comprising:
a controller for controlling HVAC&R system components, said components being operable to provide at least temperature control in an environment to be conditioned; and
energy source pricing information provided to said controller, said pricing information being utilized by said controller to control said components.

30. The HVAC&R system as set forth in claim 29, wherein the said environment is at least one of home, supermarket, office space, computer room, building structure, or mobile unit.

31. The HVAC&R system as set forth in claim 29, wherein the said HVAC&R system components is at least one of the heat pump, air conditioner, furnace, humidifier, chiller, or cooling tower.

32. The HVAC&R system as set forth in claim 29, wherein said pricing information is provided to said controller over wired or wireless network.

33. The HVAC&R system as set forth in claim 29, wherein said pricing information is provided to said controller over the Internet.

34. The HVAC&R system as set forth in claim 29, wherein pricing information is stored in a database accessible to said controller.

35. The HVAC&R system as set forth in claim 29, wherein said controller has learning capability.

36. The HVAC&R system as set forth in claim 29, wherein said pricing information is electricity pricing information.

37. The HVAC&R system as set forth in claim 36, wherein said components include at least one electricity-intensive component, and an alternative component that is less electricity-intensive.

38. The HVAC&R system as set forth in claim 37, wherein said less electricity-intensive component is weighted to be used more than said electricity-intensive component at times when electricity is higher priced.

39. The HVAC&R system as set forth in claim 38, wherein said electricity-intensive component is a heat pump, and said less electricity-intensive component is a furnace.

40. The HVAC&R system as set forth in claim 39, wherein the said furnace is supplied with natural gas or heating oil.

41. The HVAC&R system as set forth in claim 29, wherein a thermal storage media is provided to be charged during off-peak hours and release its thermal potential during high demand periods.

42. The HVAC&R system as set forth in claim 41, wherein said thermal storage media is used for cooling purposes.

43. The HVAC&R system as set forth in claim 41, wherein said thermal storage media is used for heating purposes.

44. The HVAC&R system as set forth in claim 29, wherein said energy source pricing information being utilized by said controller to select among alternative ways of achieving a desired temperature control in the environment.

45. A method of controlling an HVAC&R system comprising:
(1) providing a controller for controlling HVAC&R system components, said components being operable to provide at least temperature control in an environment to be conditioned; and
(2) providing energy source pricing information to said controller, said pricing information being utilized by said controller to determine steps for controlling said components, said energy source pricing information being utilized by said controller to select among alternative ways of achieving a desired temperature control in the environment.

46. The method as set forth in claim 45, wherein said pricing information is provided to said controller over the Internet.

47. The method as set forth in claim 45, wherein said pricing information is stored in a database accessible to said controller.

48. The method as set forth in claim 45 wherein said controller has learning capability.

49. The method as set forth in claim 45, wherein said pricing information is electricity pricing information.

50. The method as set forth in claim 49, wherein said components include at least one electricity-intensive component, and an alternative component that is less electricity-intensive.

51. The method as set forth in claim 50, wherein said less electricity-intensive component is weighted to be used more than said electricity-intensive component at times when electricity is higher priced.

52. The method as set forth in claim 51, wherein said electricity-intensive component is a heat pump, and said less electricity-intensive component is a furnace.

53. The method as set forth in claim 45, wherein a thermal storage media is provided to be charged during off-peak hours and releasing its thermal potential during high demand periods.

54. The HVAC&R system as set forth in claim 53, wherein said thermal storage media is used for cooling purposes.

55. The HVAC&R system as set forth in claim 53, wherein said thermal storage media is used for heating purposes.

56. The method as set forth in claim 55, wherein when pricing information is utilized in combination with thermal load demands to devise said HVAC&R operational strategy.

57. The method as set forth in claim 56, wherein said strategy includes particular system configuration and time schedule used for the HVAC&R system components.

58. The method as set forth in claim 45, wherein said energy source pricing information being utilized by said controller to select among alternative ways of achieving a desired temperature control in the environment
